(19) United States
(12) Patent Application Publication
(10) Pub. No.: US 2014/0377463 A1
(43) Pub. Date: Dec. 25, 2014

(54) LIQUID PROCESSING METHOD, LIQUID PROCESSING APPARATUS AND STORAGE MEDIUM

(71) Applicant: Tokyo Electron Limited, Tokyo (JP)

(72) Inventors: Yosuke Hachiya, Kumamoto (JP); Hisashi Kawano, Kumamoto (JP); Mitsunori Nakamori, Kumamoto (JP); Jun Nonaka, Kumamoto (JP); Shogo Mizota, Kumamoto (JP); Tatsuya Nagamatsu, Beaverton, OR (US); Daisuke Saiki, Kumamoto (JP); Kazuhiro Teraoka, Kumamoto (JP); Takashi Yabuta, Kumamoto (JP)

(21) Appl. No.: 14/297,768

(22) Filed: Jun. 6, 2014

(30) Foreign Application Priority Data
Jun. 20, 2013 (JP) 2013-129637
Apr. 18, 2014 (JP) 2014-086251

(51) Int. Cl. B05D 3/10; B05C 11/08; B05C 5/00; B05D 5/00; B05B 3/00; B05B 12/04; B05D 1/00; B05D 1/02; B05C 5/02

(52) U.S. Cl. CPC B05D 3/107; B05D 1/02; B05C 11/08; B05C 5/001; B05C 5/02; B05B 3/001; B05B 12/04; B05D 1/005; B05D 5/00
USPC 427/341; 427/337; 118/704

(57) ABSTRACT

Disclosed is a liquid processing method which may de-electrify the surface of a hydrophobized substrate. A substrate electrified according to a liquid processing is de-electrified by supplying a hydrophobizing liquid to a surface of the substrate subjected to the liquid processing while rotating the substrate, and performing rinsing by supplying an alkaline rinsing liquid to the hydrophobized surface of the substrate.

### CROSS-REFERENCE TO RELATED APPLICATIONS

This application is based on and claims priority from Japanese Patent Application Nos. 2013-129637, and 2014-086251 filed on Jun. 20, 2013, and Apr. 18, 2014, respectively, with the Japan Patent Office, the disclosures of which are incorporated herein in their entireties by reference.

### TECHNICAL FIELD

The present disclosure relates to a technology of performing rinsing on a substrate which is subjected to a liquid processing and then, subjected to a hydrophobizing processing.

### BACKGROUND

In a single-wafer type spin cleaning apparatus (“liquid processing apparatus”) configured to perform a liquid processing on a semiconductor wafer (“wafer”) as a substrate, for example, an alkaline or acidic chemical liquid is supplied to the surface of the wafer while the wafer is being rotated such that the chemical liquid is spread over the surface of the wafer to remove, for example, dusts or natural oxides, on the surface of the wafer. The chemical liquid remaining on the surface of the wafer is removed by, for example, a rinsing liquid. Then, when the supply of the rinsing liquid is stopped while the wafer is being rotated, the remaining rinsing liquid may be shaken off to obtain the wafer in a dried state.

However, according to the tendency toward high integration or high aspect ratio of semiconductor devices, a problem of a so-called pattern collapse has been increased, for example, in a process of removing the rinsing liquid as described above. The pattern collapse refers to a phenomenon in which, when a rinsing liquid introduced into a pattern is shaken off, the liquid remaining at the left and right sides of, for example, a convex portion of an unevenness which forms the pattern is unevenly removed, and then the balance of surface tensions that tension the convex portion in the left and right directions is lost and thus, the convex portion is collapsed in a direction in which the liquid remains in a large amount.

As a method of removing a liquid remaining on a surface of a wafer while suppressing the occurrence of pattern collapse, there is provided a technology of hydrophobizing the surface of the wafer so as to increase a contact angle between the wafer and the liquid, thereby reducing a surface tension which acts on a pattern (see, e.g., Japanese Patent Laid-Open Publication No. 2011-9537, Paragraphs 0032 to 0053 and FIG. 4).

Meanwhile, when pure water is used as a rinsing liquid for a hydrophobized wafer, the rinsing liquid may flow on the surface of the wafer so that the wafer may be electrified. Especially, in the hydrophobized wafer, the rinsing liquid may be split into liquid drops and flow on the surface of the wafer to roll. Thus, the wafer is likely to be electrified by electric charges generated during split of the liquid drops. When the wafer is electrified, the pattern on the surface of the wafer may be broken in a subsequent treatment process.

Accordingly, what is required is a technology of effectively de-electrifying the hydrophobized surface of the wafer.

### SUMMARY

The present disclosure provides a liquid processing method. The method includes hydrophobizing a surface of a substrate subjected to a liquid processing by supplying a hydrophobizing liquid to the surface of the substrate; and performing rinsing by supplying an alkaline rinsing liquid to the hydrophobized surface of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view illustrating a liquid processing apparatus according to an exemplary embodiment.

FIG. 2 is a plan view illustrating the liquid processing apparatus.

FIG. 3 is a flow chart illustrating an example of a liquid processing method which is performed in the liquid processing apparatus.

FIG. 4 is an explanatory view illustrating a relationship between a rinsing liquid temperature and a drying time after rinsing.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure has been made under the circumstances described above, and an object of the present disclosure is to provide a liquid processing method and a liquid processing apparatus which may de-electrify the hydrophobized surface of the substrate, and a storage medium storing the method.

An aspect of the present disclosure is to provide a liquid processing method. The method includes hydrophobizing a surface of a substrate subjected to a liquid processing by supplying a hydrophobizing liquid to the surface of the substrate; and performing rinsing by supplying an alkaline rinsing liquid to the hydrophobized surface of the substrate.

In the liquid processing method, the rinsing liquid has a resistivity ranging from 0.05 MΩ·cm to 0.2 MΩ·cm and a pH ranging from 9 to 12, and is an aqueous solution which contains an alkaline substance selected from an alkaline group consisting of, for example, ammonia and hydroxide. A temperature of the rinsing liquid is higher than 23° C. and not higher than 80° C. An inert gas is bubbled in the rinsing liquid such that the rinsing liquid contains a reduced amount of dissolved oxygen.

The hydrophobizing liquid hydrophobizes the surface of the substrate by substituting silanol groups on the surface of the substrate with silyl groups.

The liquid processing method further includes supplying a substitution liquid which is compatible with the hydrophobizing liquid and the rinsing liquid to the surface of the substrate after supplying the hydrophobizing liquid to the substrate and before supplying the alkaline rinsing liquid.

The liquid processing method further includes performing rinsing by supplying the alkaline rinsing liquid to the surface of the substrate subjected to the liquid processing before supplying the hydrophobizing liquid to the substrate.

Another aspect of the present disclosure is to provide a liquid processing apparatus including: a substrate holding unit configured to horizontally hold a substrate and to rotate the substrate around a vertical axis; a chemical liquid nozzle configured to supply a chemical liquid to a surface of the substrate; a hydrophobizing liquid nozzle configured to supply a hydrophobizing liquid to the surface of the substrate; a rinsing liquid nozzle configured to supply an alkaline rinsing liquid to the surface of the substrate; and a control unit configured to output a control signal. The control signal causes the liquid processing apparatus to execute supplying the chemical liquid from the chemical liquid nozzle to the surface of the substrate which is held and rotated by the substrate holding unit, hydrophobizing the surface of the substrate subjected to a liquid processing by the chemical liquid by supplying the hydrophobizing liquid from the hydrophobizing liquid nozzle to the surface of the substrate while rotating the substrate, and performing rinsing by supplying the alkaline rinsing liquid to the surface of the substrate from the rinsing liquid nozzle while rotating the substrate after the hydrophobizing liquid is supplied.

The liquid processing apparatus further includes a substitution liquid nozzle configured to supply a substitution liquid which is compatible with the hydrophobizing liquid and the rinsing liquid to the surface of the substrate. The control unit outputs a control signal which causes the liquid processing apparatus to execute supplying the substitution liquid from the substitution liquid nozzle to the surface of the substrate which rotates after supplying of the hydrophobizing liquid from the hydrophobizing liquid nozzle to the substrate and before supplying of the alkaline rinsing liquid from the rinsing liquid nozzle.

The liquid processing apparatus further includes a heating unit configured to heat the rinsing liquid supplied from the rinsing liquid nozzle at a temperature in a range of higher than 23° C. and not higher than 80° C.

The liquid processing apparatus further includes a bubbling mechanism configured to bubble an inert gas in advance in the rinsing liquid supplied from the rinsing liquid nozzle so as to reduce dissolved oxygen in the rinsing liquid.

The control unit outputs a control signal which causes the liquid processing apparatus to execute supplying the alkaline rinsing liquid from the rinsing liquid nozzle to the surface of the substrate which rotates to perform rinsing, before supplying of the hydrophobizing liquid to the substrate subjected to the liquid processing by the chemical liquid.

A further aspect of the present disclosure is to provide a computer-readable storage medium storing a computer executable program for use in a liquid processing apparatus configured to perform a liquid processing on a surface of a substrate. In the program, steps for executing the liquid processing method are set up.

In the present disclosure, since rinsing of a substrate is performed by using a conductive alkaline rinsing liquid, the surface of a hydrophobized substrate may be effectively de-electrified.

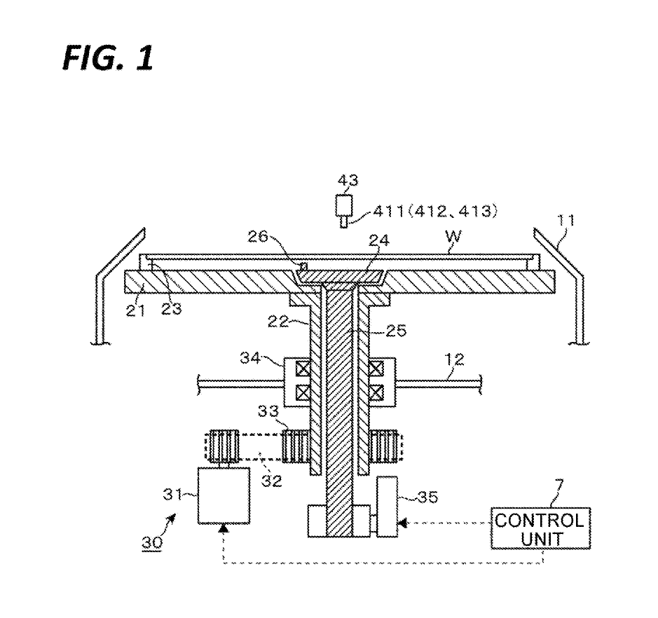

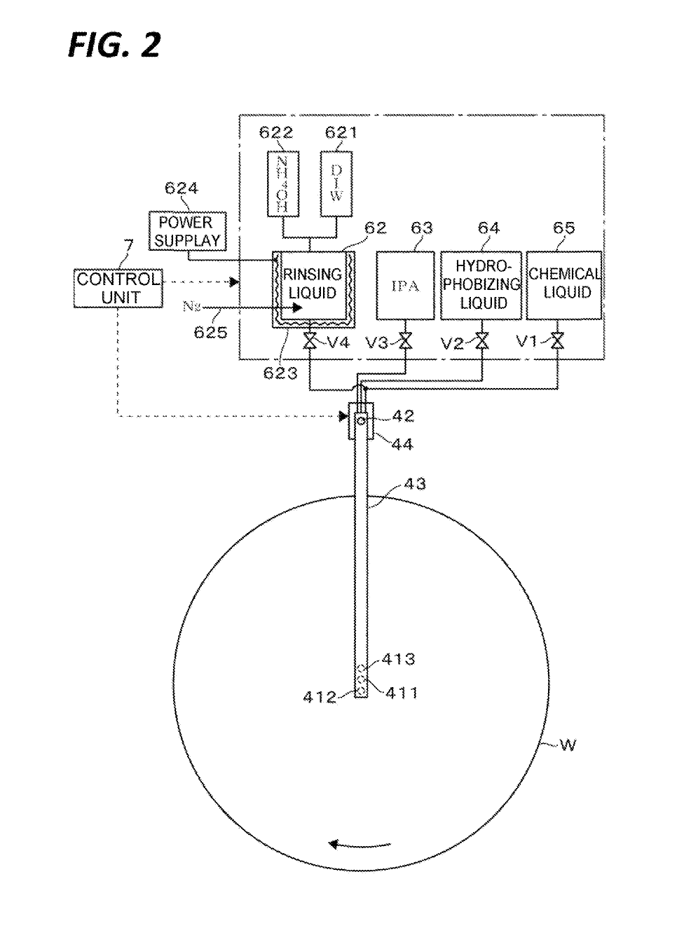

A configuration of a liquid processing apparatus according to an exemplary embodiment of the present disclosure will be described with reference to FIGS. 1 and 2. As illustrated in FIG. 1, the liquid processing apparatus includes a disk-shaped support plate 21 provided with a plurality of supporting pins 23, for example, three supporting pins 23 configured to support a wafer W horizontally, and a rotation shaft 22 connected to the bottom surface of the support plate 21 to extend vertically.

A pulley 33 is provided at a lower end side of the rotation shaft 22, and a rotation motor 31 is disposed on a lateral side of the pulley 33. A driving belt 32 is wound on the pulley 33 and a rotation shaft of the rotation motor 31 so as to constitute a rotation driving unit 30 which rotates the wafer W on the support plate 21 around a vertical axis. The rotation motor 31 may vary a rotation speed of the support plate 21, that is, a rotation speed of the wafer W supported by the support plate 21. The rotation shaft 22 is fixed via a bearing 34 to a floor board 12 of a casing in which the liquid processing apparatus is disposed. The support plate 21, the supporting pins 23, the rotation shaft 22, and the rotation driving unit 30, as described above, correspond to a substrate holding unit of the present liquid processing apparatus.

The support plate 21 has a central portion that is cut out in a circular shape, and a disk-shaped elevating plate 24 is disposed within the cut-out portion. A plurality of lift pins 26, for example, three lift pins 26, are provided on the top surface of the elevating plate 24. The lift pins 26 are configured to support the wafer W from the rear surface (the bottom surface) side during delivery of the wafer W to/from an external wafer conveyance mechanism.

A lift shaft 25 which penetrates vertically the inside of the rotation shaft 22 is connected to the bottom surface of the elevating plate 24, and an elevating mechanism 35 configured to move up and down the lift shaft 25 is provided at the lower end of the lift shaft 25.

A cup 11 configured to cover the wafer W supported by the supporting pins 23 from the circumferential edge and the diagonal upper side of the wafer W is provided in the outside of the support plate 21.

The liquid processing apparatus of the present exemplary embodiment supplies a chemical liquid to a surface of a wafer W to perform a liquid processing on the surface. In the present exemplary embodiment, SC-1 (a mixed aqueous solution of ammonia and hydrogen peroxide) is used as the chemical liquid for removing organic pollutants or particles attached on the surface of the wafer W.

The liquid processing apparatus includes a liquid nozzle 411 as a chemical liquid supply unit. The liquid nozzle 411 serves to supply a chemical liquid (SC-1) and a rinsing liquid to a central portion of the front surface (the top surface) of the wafer W which rotates. The liquid nozzle 411 corresponds to a chemical liquid nozzle in terms of supplying the chemical liquid, and corresponds to a rinsing liquid nozzle in terms of supplying the rinsing liquid.

The liquid processing apparatus is provided with a hydrophobizing liquid nozzle 412 and an IPA nozzle 413. The hydrophobizing liquid nozzle 412 is configured to supply a hydrophobizing liquid to the surface of the wafer W, and the IPA nozzle 413 is configured to supply isopropyl alcohol (IPA) to the wafer W. The IPA is compatible with both a rinsing liquid and a hydrophobizing liquid. Thus, the IPA is supplied as a substitution liquid when the processing liquids are substituted. In terms of supplying the substitution liquid to the surface of the wafer W, the IPA nozzle 413 corresponds to a substitution liquid nozzle.

These nozzles 411 to 413 are attached to a distal end portion of a nozzle arm 43. A base end portion of the nozzle arm 43 is supported by a driving unit 44 configured to rotate the nozzle arm 43 around a rotation shaft 42. When the nozzle arm 43 is rotated by the driving unit 44, the distal end portion of the nozzle arm 43 is moved so as to move the liquid nozzle 411, the hydrophobizing liquid nozzle 412, and the IPA nozzle 413 between a position above the central portion of the wafer W (the rotation center of the wafer W) and a position retreated laterally from the position above the wafer W. Although the cup 11 is omitted in FIG. 2 for the convenience of illustration, the position to which the nozzles 411, 412, and 413 are retreated is set to be more outside than the cup 11. Here, the liquid nozzle 411, the hydrophobizing liquid nozzle 412, and the IPA nozzle 413 are not limited to the case where they are provided in the common nozzle arm 43. Each of the nozzles 411, 412 and 413 may individually employ, for example, a dedicated nozzle arm or a dedicated moving mechanism.

Liquid flow paths (not illustrated) are provided in the nozzle arm 43 and connected to the liquid nozzle 411, the hydrophobizing liquid nozzle 412, and the IPA nozzle 413, respectively.

The flow path connected to the liquid nozzle 411 is connected to a rinsing liquid supply unit 62, and a chemical liquid supply unit 65 each of which is provided with a tank of each processing liquid (the chemical liquid and the rinsing liquid), and a flow rate control mechanism. The rinsing liquid supplied from the rinsing liquid supply unit 62 of the present exemplary embodiment also serves to de-electrify the surface of the wafer W which has been electrified during a liquid processing.

In this respect, an alkaline rinsing liquid is supplied from the rinsing liquid supply unit 62. The rinsing liquid supply unit 62 is connected to an ammonia water supply unit 622 configured to supply ammonia water adjusted to have a predetermined concentration, and a DIW supply unit 621 configured to supply deionized water (“DIW”). In the rinsing liquid supply unit 62, ammonia water and DIW are supplied at a predetermined supply ratio from the ammonia water supply unit 622 and the DIW supply unit 621. As a result, dilute ammonia water (the alkaline rinsing liquid) is prepared within the tank of the rinsing liquid supply unit 62 in a mixing ratio of ammonia and water of 1:500 based on weight.

In terms of de-electrifying the wafer W, the alkaline rinsing liquid supplied from the rinsing liquid supply unit 62 has a resistivity (a specific resistance) ranging, preferably, from 0.05 MΩ·cm to 0.2 MΩ·cm, and a pH ranging, preferably, from 9 to 12.

A heating unit 623 is provided in the above-described rinsing liquid supply unit 62. The heating unit 623 is configured to heat the alkaline rinsing liquid stored within the rinsing liquid supply unit 62 to improve a cleaning effect. For example, the heating unit 623 is provided with a heater, and increases or decreases the power supplied from a power supply unit 624 based on a temperature detected by a temperature detecting unit (not illustrated) or a temperature of the rinsing liquid within the rinsing liquid supply unit 62 so as to heat the rinsing liquid to a predetermined temperature. The temperature of the rinsing liquid within the rinsing liquid supply unit 62 is adjusted such that the rinsing liquid is supplied to the wafer W at a temperature in a range of, for example, higher than 23° C. (room temperature) and not higher than 80° C., preferably higher than 23° C. and not higher that 60° C.

An inert gas supply line 625 configured to supply an inert gas such as, for example, a nitrogen gas, to the rinsing liquid is connected to the rinsing liquid supply unit 62. The distal end portion of the inert gas supply line 625 is inserted in the rinsing liquid within the rinsing liquid supply unit 62, and constitutes a bubbling mechanism configured to bubble the inert gas supplied from the inert gas supply line 625 in the rinsing liquid. The rinsing liquid may contain dissolved oxygen, and the oxygen desorbs silyl groups from the surface of the wafer W which is silylated during hydrophobizing to be described later, which results in reduction of the hydrophobicity. Here, when the rinsing liquid within the rinsing liquid supply unit 62 is bubbled by the inert gas supplied from the inert gas supply line 625, the dissolved oxygen may be reduced in the rinsing liquid to be supplied to the wafer W. The inert gas used for bubbling is exhausted from the rinsing liquid supply unit 62 through an exhaust line (not illustrated).

The above-described supply units 62 and 65 of the respective processing liquids are connected to the liquid flow path through connecting tubes. When opening/closing valves V1 and V4 provided in the connecting tubes are opened or closed, the respective processing liquids (the chemical liquid and the rinsing liquid) may be supplied from the liquid nozzle 411 to the wafer W in a switching manner. In order to suppress the temperature of the rinsing liquid heated up by the heating unit 623 from being lowered, the liquid flow path of the rinsing liquid from the rinsing liquid supply unit 62 to the nozzle arm 43 is kept warm.

The flow path connected to the hydrophobizing liquid nozzle 412 is connected to a hydrophobizing liquid supply unit 64 provided with a tank of a hydrophobizing liquid, for example, trimethyl silyl dimethyl amine (hereinafter, referred to as TMSDMA), and a flow rate control mechanism. The hydrophobizing liquid supply unit 64 is connected to the liquid flow path through a connecting tube. When an opening/closing valve V2 provided in the connecting tube is opened or closed, the hydrophobizing liquid may be supplied from the hydrophobizing liquid nozzle 412 to the wafer W.

The TMSDMA hydrophobizes the surface of the wafer W by silylation of the surface, and thus serves to increase the contact angle between the wafer W and the rinsing liquid when the rinsing liquid used for rinsing is removed. As a result, a force which acts on a pattern formed on the surface of the wafer W is reduced, and thus, the liquid may be removed without causing pattern collapse. In the present exemplary embodiment, silylation refers to a process of hydrophobizing the surface of the wafer W by replacing hydrophilic functional groups bonded to Si atoms on the surface of the wafer W, for example, OH groups (silanol groups), with hydrophobic functional groups (silyl groups) including Si atoms. In a case of the TMSDMA, substitution with trimethyl silyl groups is performed.

The flow path connected to the IPA nozzle 413 is connected to an IPA supply unit 63 provided with a tank of IPA as a solvent, and a flow rate control mechanism. When an opening/closing valve V3 provided in a connecting tube which connects the liquid flow path to the IPA supply unit 63 is opened or closed, the IPA as a substitution liquid may be supplied from the IPA nozzle 413 to the wafer W.

The liquid processing apparatus provided with the above described configuration is connected to a control unit 7 as illustrated in FIGS. 1 and 2. The control unit 7 includes, for example, a computer (not illustrated) provided with a CPU and a storage unit. The storage unit stores a program in which a group of steps (commands) for controlling the operation of the liquid processing apparatus are set up. The operation includes rotating a wafer W supported by the support plate 21, performing a liquid processing, hydrophobizing, and/or drying of the wafer W by supplying processing liquids in a switching manner based on a predetermined schedule, and then performing carrying-out of the wafer W. The program is stored in a storage medium such as, for example, a hard disk, a compact disk, a magneto-optical disk, and a memory card, and is installed to the computer therefrom.

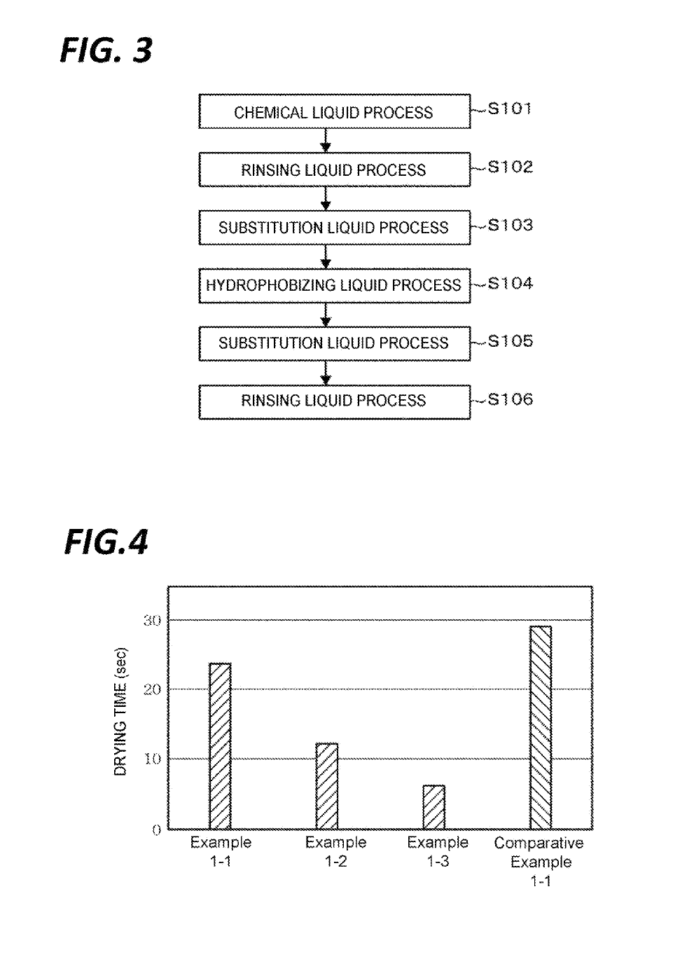

Hereinafter, the operation of the liquid processing apparatus having these functions will be described with reference to a flow chart of FIG. 3.

The liquid processing apparatus stands by in a state where the nozzles 411, 412 and 413 are retracted to the outside of the cup 11, and the support plate 21 is stopped. When an external wafer conveyance mechanism advances a fork which holds a wafer W to a position above the support plate 21, the elevating plate 24 is moved up to intersect with the fork so that the wafer W is delivered to the lift pins 26 of the elevating plate 24.

After the fork is retreated from the position above the support plate 21, the elevating plate 24 is moved down such that the wafer W is placed on the supporting pins 23 of the support plate 21. Then, the rotation motor 31 is operated so as to rotate the wafer W on the support plate 21. Then, when the rotation speed of the wafer W reaches a predetermined speed, the nozzles 411, 412 and 413 are moved to a position above the central portion of the wafer W.

Then, SC-1 is supplied from the liquid nozzle 411 for a predetermined time to remove organic pollutants or particles (a chemical liquid process in FIG. 3, step S101). Subsequently, the rotation speed of the wafer W is increased, and the processing liquid to be supplied from the liquid nozzle 411 is switched to a rinsing liquid so as to perform rinsing, and wash away the SC-1 on the surface of the wafer W (a rinsing liquid process, step S102).

Here, electric charges generated on the surface of the wafer W during the chemical liquid process are neutralized by being bonded with ions (e.g., OH⁻ ions or NH₄⁺ ions) included in the alkaline rinsing liquid. Thus, the wafer W is de-electrified.

Since the alkaline rinsing liquid is used, the surface of the wafer W covered with the rinsing liquid has a negative zeta potential. Meanwhile, in general, many of particles attached on a wafer W tend to have a higher zeta potential in absolute value (farther from an isoelectric point) in an alkaline rinsing liquid causing a negative zeta potential than in an acidic liquid causing a positive zeta potential. Accordingly, when the alkaline rinsing liquid is used, electrical repulsion between the wafer W and the particles having negative zeta potentials is increased so that the particles may be easily separated from the wafer W.

Further, the alkaline rinsing liquid hardly causes corrosion of wiring of a metal such as, for example, copper (Cu) unlike the acidic liquid, and thus, is excellent as the rinsing liquid in this regard. The wafer W is de-electrified after the rinsing is completed, and thus, particles in the surrounding atmosphere are hard to attach to the wafer W.

When the SC-1 has been washed away by the rinsing liquid, and the supply of the alkaline rinsing liquid for a time required for de-electrifying the wafer W has been supplied, the supply of the rinsing liquid is stopped, and IPA as a substitution liquid is supplied from the IPA nozzle 413 to the surface of the wafer W which rotates (a substitution liquid process, step S103). When the rinsing liquid is substituted with the IPA, the supply of the IPA is stopped. Then, a hydrophobizing liquid is supplied from the hydrophobizing liquid nozzle 412 to the surface of the wafer W which rotates so that the wafer W is hydrophobized (a hydrophobizing liquid process, step S104). In each process, the rotation speed of the wafer W is set to be a rotation speed that enables the substitution liquid or the hydrophobizing liquid to be uniformly spread over the surface of the wafer W.

At a point of time when the surface of the wafer W is hydrophobized by the hydrophobizing liquid, the supply of the hydrophobizing liquid is stopped, and the IPA as a substitution liquid is supplied from the IPA nozzle 413 to the surface of the wafer W which rotates (a substitution liquid process, step S105). When the hydrophobizing liquid is substituted with the IPA, the rotation speed of the wafer W is increased. Then, the processing liquid to be supplied from the liquid nozzle 411 is switched to the rinsing liquid so as to perform rinsing and wash away the IPA on the surface of the wafer W (a rinsing liquid process, step S106).

Here, electric charges generated on the surface of the wafer W during the substitution liquid process, the hydrophobizing liquid process and the subsequent substitution liquid process (steps S103 to S105) are neutralized by being bonded with ions included in the alkaline rinsing liquid. Thus, the wafer W is de-electrified. At this time as well, when the alkaline rinsing liquid is used, negative zeta potentials formed on the wafer W and around the particles may become high. Thus, it is possible to achieve an acting effect of easily separating the particles, and an acting effect of suppressing corrosion of wiring of a metal such as, for example, copper. The wafer W is de-electrified after the rinsing is completed, and the pattern on the surface of the wafer W is suppressed from being broken. Further, particles in the surrounding atmosphere are hard to attach to the wafer W.

In the hydrophobizing liquid process which is performed after the liquid processing, reaction byproducts generated when the surface of the wafer W is silylated may be attached on the surface of the wafer W. Thus, the rinsing liquid is required to have an ability to remove the attached substances. In this regard, the rinsing liquid is heated by the heating unit 623 to a temperature higher than room temperature (23° C.) and thus, may exhibit a higher cleaning ability than the rinsing liquid supplied at room temperature.

The rinsing liquid to be supplied to the wafer W is bubbled in advance by an inert gas so that the oxygen dissolved therein is reduced. This suppresses occurrence of a phenomenon where the oxygen in the rinsing liquid desorbs silyl groups from the silylated surface of the wafer W, thereby maintaining the hydrophobicity of the wafer W.

Further, the SC-1 used for a liquid processing and the alkaline rinsing liquid for rinsing include ammonia and have a lower surface tension than DIW. Thus, during these processings, a pattern collapse may be suppressed.

When the IPA has been washed away by the rinsing liquid, and the supply of the alkaline rinsing liquid has been supplied for a time required for de-electrifying the wafer W, the supply of the rinsing liquid is stopped.

When the drying of the wafer W has been completed while the wafer W is continuously rotated, the nozzles 411, 412, and 413 are retreated from the position above the wafer W, and the rotation of the wafer W is stopped. Here, when the rinsing has been performed by using the heated rinsing liquid, a time required for drying the wafer W may be reduced. Then, the elevating plate 24 is moved up to raise the wafer W, and then the wafer W which has been processed is delivered to the external wafer conveyance mechanism, and the elevating plate 24 is moved down to await the carrying-in of a following wafer W.

The liquid processing apparatus according to the present exemplary embodiment has the following effects. Since the hydrophobized wafer W is rinsed by using a conductive alkaline rinsing liquid, and then dried, the hydrophobized surface of a wafer W may be effectively de-electrified. Accordingly, the pattern on the surface of the wafer W may be suppressed from being collapsed and then broken.

Further, an alkaline rinsing liquid is used in each rinsing liquid process (rinsing) which is performed several times, for example, after a chemical liquid process. Thus, a wafer W which has been electrified by previous processes may be gradually de-electrified. As a result, a time required for supplying the alkaline rinsing liquid for de-electrification in the final rinsing liquid process may be reduced as compared to a case where the alkaline rinsing liquid is used only in the final rinsing liquid process (step S106).

Besides using the dilute ammonia water, the alkaline rinsing liquid may be prepared to have a resistivity and a pH in the above described ranges (resistivity 0.05 MΩ·cm to 0.2 MΩ·cm, pH 9 to 12) by dissolving an alkaline substance which is a hydroxide such as, for example, sodium hydroxide (NaOH) or potassium hydroxide (KOH) in DIW.

A hydrophobizing liquid used as hydrophobic agent is not limited to TMSDMA. For example, hexamethyldisilizane (HMDS), trimethylsilyldiethylamine (TMSDEA), dimethyl(dimethylamino)silane (DMSDMA), or 1,1,3,3-tetramethyldisilane (TMDS) may be used.

In addition, the kind of a chemical liquid used for processing the wafer W is not limited to SC-1. For example, a diluted hydrofluoric acid (DHF) solution for removing pollutants such as, for example, particles, on the surface of the wafer W, or SC-2 (a mixed aqueous solution of hydrochloric acid and hydrogen peroxide) for removing metal impurities on the surface of the wafer W may be used. Here, when generation of a salt may be problematic due to supply of the acidic chemical liquid and the alkaline rinsing liquid to the common liquid nozzle 411, the chemical liquid and the rinsing liquid may be supplied by using separate nozzles, respectively.

Further, the substitution liquid for the hydrophobizing liquid and the rinsing liquid is not limited to IPA. For example, acetone may be used.

Since a hydrophobic agent which is easily mixed with a rinsing liquid (water) has recently been developed, a substitution liquid process using, for example, IPA may not be necessarily performed.

### EXAMPLE

### Test 1

An alkaline rinsing liquid containing ammonia was heated and supplied to a rotating wafer W, and a time until the rinsing liquid was dried was measured.

A. Test Method

The rinsing liquid was supplied at a flow rate of 1.5 L/min for 60 sec to the top surface of a wafer W which was supported by a support plate 21 of a liquid processing apparatus and rotated at 1000 rpm. After the supply of the rinsing liquid was stopped, a time until a liquid film disappeared from the surface of the wafer W was measured. The time until the liquid film disappeared was determined based on a time until an interference fringe observed due to the formation of the liquid film disappeared.

### Example 1-1

An alkaline rinsing liquid containing 3 ppm by mass of ammonia in DIW was heated to 30° C. and rinsing was performed. Then, the drying time was measured.

### Example 1-2

The drying time was measured under the same condition as in Example 1-1 except that the temperature of the alkaline rinsing liquid was 45° C.

### Example 1-3

The drying time was measured under the same condition as in Example 1-1 except that the temperature of the alkaline rinsing liquid was 60° C.

### Comparative Example 1-1

The drying time was measured under the same condition as in Example 1-1 except that DIW at 23° C. (room temperature) was used as a rinsing liquid.

B. Test Result

The results of Examples 1-1 to 1-3 and Comparative Example 1-1 are represented in FIG. 4. The vertical axis in FIG. 4 indicates the drying time of the rinsing liquid which was measured in each test.

According to the test results represented in FIG. 4, it was found that the drying time was reduced as the temperature of an alkaline rinsing liquid was increased in the order of Example 1-1 (30° C.)→Example 1-2 (45° C.)→Example 1-3 (60° C.). In contrast, in Comparative Example 1-1 using DIW at room temperature, the drying time was longer than Examples 1-1 to 1-3.

### Test 2

Rinsing of a wafer W was performed while the kind of a rinsing liquid was varied. Then, a surface potential of the wafer W after drying was measured.

A. Test Method

A rinsing liquid at 60° C. was supplied for 30 sec under the same condition as in Test 1, and the wafer W was rotated to be dried after the supply of the rinsing liquid was stopped. Then, the surface potential of the wafer W was measured by a surface electrometer.

### Example 2-1

Rinsing was performed using a rinsing liquid of which the ammonia content was adjusted so that the resistivity was 0.15 MΩ·cm, and then, the surface potential of the wafer W after drying was measured.

### Comparative Example 2-1

DIW was used as a rinsing liquid to perform rinsing, and then the surface potential of the wafer W after drying was measured. The resistivity of DIW was 18 MΩ·cm.

B. Test Result

The results of Example 2-1 and Comparative Example 2-1 are represented in Table 1.

TABLE 1

| | | Comparative |
|---|---|---|
| | Example 2-1 | Example 2-1 |
| Average surface potential [V] | 0.12 | −1.15 |
| Maximum surface potential [V] | 2.25 | 4.57 |
| Minimum surface potential [V] | −0.58 | −4.15 |

According to the results of Example 2-1 and Comparative Example 2-1, when any of the rinsing liquids was used, distribution of surface potentials on the wafer W was observed. As represented in Table 1, in comparison by absolute values, the average surface potential of the wafer W in Example 2-1 was reduced to about one tenth of that in Comparative Example 2-1. Thus, it was found that the surface of the wafer W may be effectively de-electrified when the alkaline rinsing liquid is used. Also, it may be appreciated that in both the maximum surface potential and the minimum surface potential, the wafer W in Example 2-1 has a lower surface potential value than the wafer W in Comparative Example 2-1, and that the de-electrification effect is achieved over the front surface of the wafer W.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A liquid processing method comprising:
hydrophobizing a surface of a substrate subjected to a liquid processing by supplying a hydrophobizing liquid to the surface of the substrate; and
performing rinsing by supplying an alkaline rinsing liquid to the hydrophobized surface of the substrate.

2. The liquid processing method of claim 1, wherein the rinsing liquid has a resistivity ranging from 0.05 MΩ·cm to 0.2 MΩ·cm.

3. The liquid processing method of claim 1, wherein the rinsing liquid has a pH ranging from 9 to 12.

4. The liquid processing method of claim 1, wherein the rinsing liquid is an aqueous solution which contains an alkaline substance selected from an alkaline group consisting of ammonia and hydroxide.

5. The liquid processing method of claim 1, wherein a temperature of the rinsing liquid is higher than 23° C. and not higher than 80° C.

6. The liquid processing method of claim 1, wherein an inert gas is bubbled in the rinsing liquid such that the rinsing liquid contains a reduced amount of dissolved oxygen.

7. The liquid processing method of claim 1, wherein the hydrophobizing liquid hydrophobizes the surface of the substrate by substituting silanol groups on the surface of the substrate with silyl groups.

8. The liquid processing method of claim 1, further comprising:
supplying a substitution liquid which is compatible with the hydrophobizing liquid and the rinsing liquid to the surface of the substrate after supplying the hydrophobizing liquid to the substrate and before supplying the alkaline rinsing liquid.

9. The liquid processing method of claim 1, further comprising:
performing rinsing by supplying the alkaline rinsing liquid to the surface of the substrate subjected to the liquid processing before supplying the hydrophobizing liquid to the substrate.

10. A liquid processing apparatus comprising:
a substrate holding unit configured to horizontally hold a substrate and to rotate the substrate around a vertical axis;
a chemical liquid nozzle configured to supply a chemical liquid to a surface of the substrate;
a hydrophobizing liquid nozzle configured to supply a hydrophobizing liquid to the surface of the substrate;
a rinsing liquid nozzle configured to supply an alkaline rinsing liquid to the surface of the substrate; and
a control unit configured to output a control signal which causes the liquid processing apparatus to execute supplying the chemical liquid from the chemical liquid nozzle to the surface of the substrate which is held and rotated by the substrate holding unit, hydrophobizing the surface of the substrate subjected to a liquid processing by the chemical liquid by supplying the hydrophobizing liquid from the hydrophobizing liquid nozzle to the surface of the substrate while rotating the substrate, and performing rinsing by supplying the alkaline rinsing liquid to the surface of the substrate from the rinsing liquid nozzle while rotating the substrate after the hydrophobizing liquid is supplied.

11. The liquid processing apparatus of claim 10, further comprising:
a substitution liquid nozzle configured to supply a substitution liquid which is compatible with the hydrophobizing liquid and the rinsing liquid to the surface of the substrate,
wherein the control unit outputs a control signal which causes the liquid processing apparatus to execute supplying the substitution liquid from the substitution liquid nozzle to the surface of the substrate which rotates after supplying of the hydrophobizing liquid from the hydrophobizing liquid nozzle to the substrate and before supplying of the alkaline rinsing liquid from the rinsing liquid nozzle.

12. The liquid processing apparatus of claim 10, further comprising:
a heating unit configured to heat the rinsing liquid supplied from the rinsing liquid nozzle at a temperature in a range of higher than 23° C. and not higher than 80° C.

13. The liquid processing apparatus of claim 10, further comprising:
a bubbling mechanism configured to bubble an inert gas in advance in the rinsing liquid supplied from the rinsing liquid nozzle so as to reduce dissolved oxygen in the rinsing liquid.

14. The liquid processing apparatus of claim 10, wherein the control unit outputs a control signal which causes the liquid processing apparatus to execute supplying the alkaline rinsing liquid from the rinsing liquid nozzle to the surface of the substrate which rotates to perform rinsing, before supplying of the hydrophobizing liquid to the substrate subjected to the liquid processing by the chemical liquid.

15. A computer-readable storage medium storing a computer executable program for use in a liquid processing apparatus configured to perform a liquid processing on a surface of a substrate, wherein in the program, steps for executing the liquid processing method of claim 1 are set up.
